(19) United States
(12) Patent Application Publication
(10) Pub. No.: US 2023/0311244 A1
(43) Pub. Date: Oct. 5, 2023

(54) APPARATUS AND METHOD FOR SEMICONDUCTOR PACKAGE FAILURE ANALYSIS

(71) Applicant: Gatan, Inc., Pleasanton, CA (US)

(72) Inventors: Steven Thomas COYLE, Alameda, CA (US); Thijs C. HOSMAN, San Francisco, CA (US); John Andrew HUNT, Fremont, CA (US); Michael Patrick HASSEL-SHEARER, Wilmington, NC (US)

(73) Assignee: Gatan, Inc., Pleasanton, CA (US)

(21) Appl. No.: 18/023,412

(22) PCT Filed: Aug. 27, 2021
(86) PCT No.: PCT/US2021/047844

§ 371 Date: Feb. 27, 2023

Related U.S. Application Data
(60) Provisional application No. 63/071,456, filed on Aug. 28, 2020.

(51) Int. Cl. B23K 26/0622; B23K 26/06; B23K 26/082; B23K 26/122; B23K 26/38; B23K 26/70

(52) U.S. Cl. CPC B23K 26/0624; B23K 26/0648; B23K 26/082; B23K 26/122; B23K 26/38; B23K 26/705; B23K 2101/40

(57) ABSTRACT

A pulsed laser apparatus for milling a sample is described. The apparatus includes a pulsed laser, a scan head for scanning a beam from the pulsed laser across the sample and an F-theta lens for focusing the scanned beam onto the sample. The apparatus may also include a liquid bath for milling the sample under the liquid, such as water. Methods of pulsed laser milling are also described.

### CROSS REFERENCE TO RELATED APPLICATIONS

This PCT application claims priority to U.S. Provisional Application No. 63/071,456 filed on Aug. 28, 2020 and titled Apparatus and Method for Semiconductor Package Failure Analysis, the entire disclosure of which is incorporated here by reference.

### BACKGROUND

Ever-increasing semiconductor density requirements have led to devices termed “advanced packages,” which consist of multiple integrated circuits housed within a single package. These packages are becoming a preferred alternative to increased density on individual microcircuits. Advanced packages are also being used in mobile devices where ultra-thin packages with increased functionality are required.

Integrating multiple die in a single package introduces different process development issues and failure modes compared to a single device per package. These include interconnect failures between silicon devices due to metallurgy associated with interdiffusion and brittle phase formation; cracks in through-silicon via insulator sleeves causing shorts to the silicon; stress in the devices causing delamination of the devices as they bow pulling apart the stack devices; overheating; and misalignment of the interconnects. In some cases, packaging houses are not stacking die but stacking wafers and dicing after the completion of the stacking process. In this case small misalignments from the center of the wafer stack become large toward the edge of the wafer.

Identification of the root cause of many of the above failure modes requires point cross sectioning the package. Many traditional failure analysis techniques cannot, however, make cross sections in advanced packages that can be as large as 50 mm×50 mm and 6 mm thick.

For example, focused ion beam (FIB) (Ga or Plasma) cannot cross section depths greater than a few 100 microns, let alone the depths that may be required to find the root cause of the failure in an advanced package. Broad Argon Beam tools lack the current to produce lengths >10 mm and depths >2 mm polished regions in reasonable times. The only current solution is a slow speed, low damage saw. However, this technique often produces delamination and cracks due to the stresses and dissimilar materials present.

### BRIEF DESCRIPTION OF THE DRAWINGS

FIG. 1A is a block diagram showing a portion of a pulsed laser sample ablation system;

FIG. 1B is a diagram showing a further portion of the pulsed laser sample ablation system of FIG. 1A;

FIG. 2 is a flow diagram of an exemplary process for cross sectioning a sample;

FIG. 3 is a flow diagram of an exemplary process for cross sectioning a sample; and

FIG. 4 is a flow diagram of an exemplary process for cross sectioning a sample.

### DETAILED DESCRIPTION OF PREFERRED EMBODIMENTS

Those skilled in the art will recognize other detailed designs and methods that can be developed employing the teachings of the present invention. The examples provided here are illustrative and do not limit the scope of the invention, which is defined by the attached claims. The following detailed description refers to the accompanying drawings. The same reference numbers in different drawings may identify the same or similar elements.

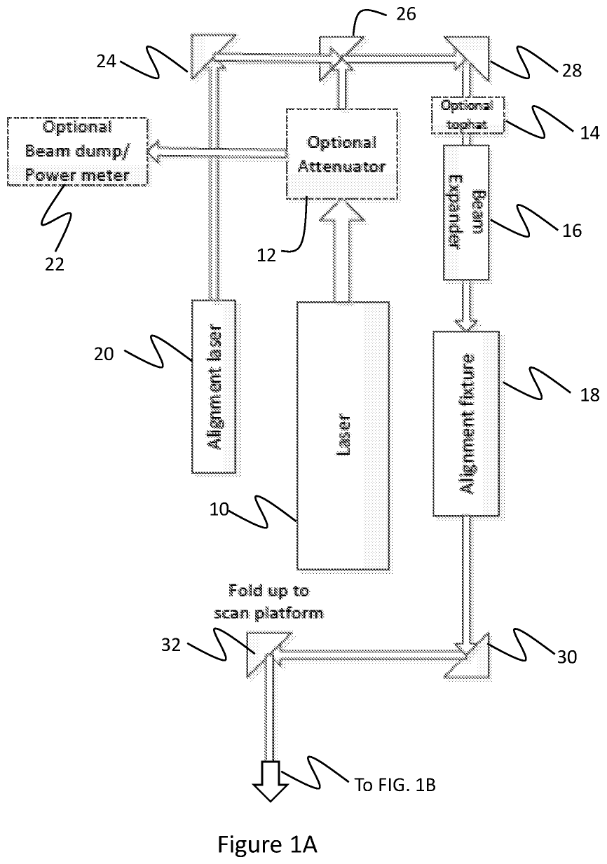

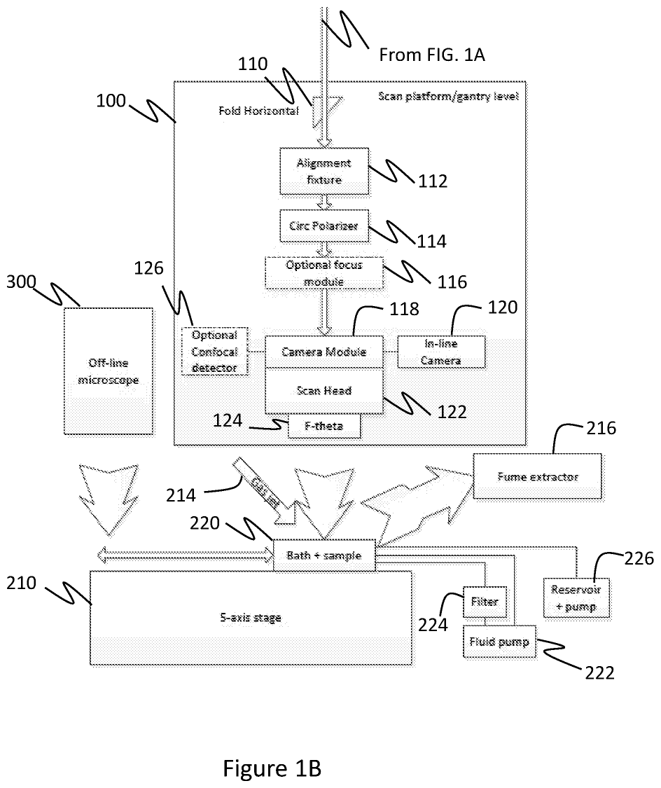

FIGS. 1A and 1B illustrate a block diagram of an apparatus according to embodiments described herein that uses a pulsed laser that is focused onto and scanned across the surface of an advanced package sample for the purpose of removing material by laser ablation to create a cross-section view of the sample. After ablation, the sample can be imaged in a microscope, such as x-ray or electron microscope, and/or analyzed by a spectroscopic method. FIG. 1A shows, primarily, the pulsed laser components and FIG. 1B shows the components associated with the handling of a sample.

With reference to FIG. 1A, following the primary components in the laser beam path, are a pulsed laser 10, an attenuator 12, a “top-hat” beam-shaper 14, a beam expander 16 and an alignment fixture 18. The pulsed laser 10 may exhibit variable control over laser power, pulse length, repetition rate, and a mechanical shutter. Types of pulsed laser include solid state mode-locked lasers, solid state Q-switched lasers, and fiber mode-locked lasers. The pulsed laser 10 may also support multiple wavelengths via frequency doubling crystals. The optional top hat beam-shaper 14 converts a Gaussian beam profile to a pseudo-top hat profile. The top hat beam-shaper can be used to improve illumination uniformity across a sample surface. The attenuator 12 can be included if the laser 10 does not have fine enough control over the output power. If the attenuator 12 is used, the unused light is deflected into a beam dump and power meter 22. The beam expander 16 changes the diameter of the laser beam profile to match the entrance aperture of the scanner, which is detailed in FIG. 1B. Adjusting the beam diameter also helps determine the spot size at the sample. The alignment fixture 18 comprises a set of apertures that the laser beam is aligned to. If the beam drifts at the laser 10, it can be aligned to the alignment fixture and the rest of the beam path after the alignment fixture will not have to be aligned. Also shown in FIG. 1 are mirrors 24, 26, 28, 30 and 32 that are arranged to position the laser beam advantageously to the various components in the apparatus.

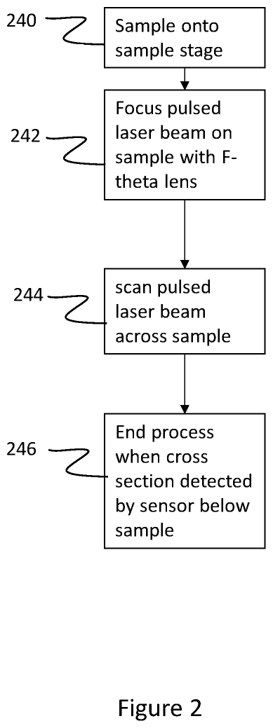

FIG. 1B shows a scan platform 100, which the laser beam from the components described in FIG. 1 enters at an alignment fixture 112. This alignment fixture serves as a reference point for the components in FIG. 2, so that once the position of the beam entering the alignment fixture 112 needs is adjusted the beam is then aligned as to all of the components downstream of this alignment fixture. 112. Following the alignment fixture 112 is a circular polarizer 114. The circular polarizer 114 is a waveplate that converts the beam from linearly polarized light to circularly polarized light. This is useful for ablating certain metals and other crystals that have a dependence between ablation speed and crystal orientation.

In some embodiments, a focus module 116 may be included in the beam path. The focus module 116 comprises a motorized optical element that can shift the focal position of the laser beam at the sample. A focus module 116 can be used in place of a motorized z-stage at the sample. Following the focus module 116 (or circular polarizer 114 if no focus module is used) is a camera module 118. As shown schematically in FIG. 1B, the camera module 118 comprises a beam splitter to pass primary laser light to the sample and deflect light reflected from the sample into an in-line camera 120 or optional confocal detector 126 or optional spectrometer (not shown). The camera module 118 allows for through-the-lens imaging of the sample as well as optional height detection using a confocal detector 126 and spectroscopy of the plasma plume when these devices are included in the system.

Following the camera module is a scan head 122. The scan head 122 comprises two actuated mirrors to scan the laser beam in orthogonal directions at the sample surface. Alternatively the scan head can comprise a rotating polygon mirror. Following the scan head 122, is an F-theta lens 124, which focuses the laser beam onto the sample surface. An F-theta lens allow the laser beam to be scanned while maintaining focus across the field of view, however, a different type of lens may be used if a reduced field of view is acceptable.

FIG. 1B also shows a five-axis sample stage 210 on which a sample rests for laser ablation by the apparatus. In some embodiments, the sample stage 210 includes a mechanism to move the sample between the process position, an off-line microscope position, and a loading position. The sample stage 210 also moves different regions of the sample into the process position and sets the height of the sample so the region of interest is in the focal plane. The sample stage 210 can also tip and tilt a sample. As shown, the sample stage 210 may also include a liquid bath 220 for cooling the sample during ablation. The liquid in the bath may be sourced by a reservoir and pump 226. During ablation, the fluid from reservoir and pump 226 may be circulated through a filter 224 by a circulation pump 222. A fume extractor 216 is included to safely remove vaporized products of ablation, and optionally for analysis. A gas jet 214 may be provided to remove ablated material during a cut. FIG. 1B also shows an off-axis optical microscope 300, which may be an optical microscope or an electron microscope. In an embodiment of the invention the 5-axis stage 210 is located so as to be able to transfer the sample for viewing in the microscope 300.

According to an embodiment described herein, the laser beam may be held in a fixed position while the 5-axis stage 210 is moved to mill a portion of the sample. In other embodiments, a combination of movement of the laser beam by the scan head 112 and movement of the 5-axis stage is used for milling the sample.

According to embodiments described herein, the pulsed laser 10 is operated between 1 and 50 Watts of power. In addition, the wavelength of the pulsed laser may be between about 1050 nanometers (nm) and 350 nm. According to further aspects described herein, the pulse length is between 250 femotseconds (fs) and 750 picoseconds (ps). According to a further aspect, the pulsed laser has a spot size between 10 nm and 100 nm at the sample.

Consistent with embodiments described herein, the sample may be held under liquid, such as water, in the bath 220, with the top surface of the sample up to 1.5 mm under the surface of the liquid. A fluid recirculating system may include circulation pump 222 and filter 224 as described briefly above. Circulation pump 222 may operate to pump the liquid through filter 224 and maintain flow during processing so the liquid in bath 220 stays clear and to eliminate bubbles from the laser ablation process. The recirculating system may include a liquid level adjustment to compensate for different size samples and to remove all liquid in case a sample needs to be processed without the liquid. The recirculating system may include a capability to adjust the liquid level during processing based on either processing time or measured level to replace liquid lost by splattering or evaporation, as well as to keep the liquid level at a fixed height above the surface that is being ablated. This is necessary to keep the depth of liquid above the ablated surface constant while the level of the ablated surface is gradually lowered during the ablation process.

An additive may be added to the liquid in bath 220 so that the liquid “wet's” the surface of the sample. In some implementations consistent with embodiments described herein, the additive may be an alcohol or a soap. This additive may also be chosen to reduce oxidation or selectively enhance ablation of the sample, such as a weak acid for reducing of metal oxidation.

In a further aspect, the laser may be paused to allow liquid to flow back into the ablated region. In a further aspect, a small region within a larger region to be milled is first milled entirely through the sample. This allows liquid to flow into the milling region from below the sample to cool the ablation region of the sample while the larger region is being milled.

According to another aspect, the pulsed laser operates in a burst mode, where a burst of pulses is continuously repeated at a fixed repetition rate. In an aspect of the invention, the number of pulses in each burst can vary between 2 and 50.

According to a yet another aspect, the system includes a spectrometer to analyze the plasma plume as extracted by the plume extractor 216. The spectrum analysis of the plasma plume is useful to determine the material being ablated. This can be used for ablation end point detection.

According to another aspect, the system includes a light detector, or a mirror and a light detector, located underneath the sample and protected by a layer of liquid (e.g., a depth of >5 mm) to prevent ablation of the detector/mirror/window. The light detector or mirror/light detector operates to detect the end point of a cross section. The detector signal can be synchronized to the laser scanner system to create a shadow image of the cross-section edge. The light detector may not have any dimensional information, but by synchronizing the detection of light with the laser position, a 2D image can be created based on the raster effect of the laser beam scanning across the sample.

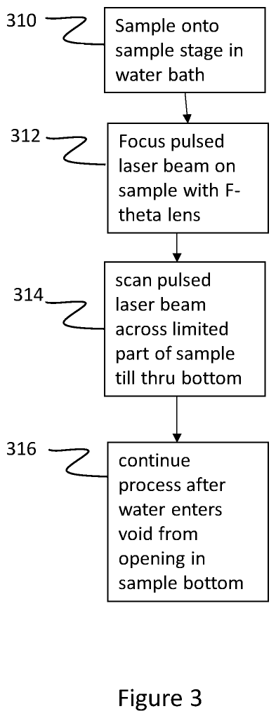

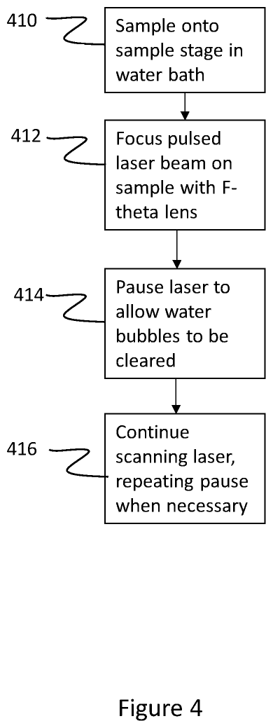

FIG. 2 is a flow diagram of an exemplary process for cross sectioning a sample according to an aspect of the invention. Reference is made here and for FIGS. 3 and 4 to the apparatus of FIGS. 1A and 1B, although the processes are not limited to that exemplary apparatus. Step 240 provides for positioning a sample to be cross-sectioned on a sample stage 210. At step 242, a pulsed laser beam is focused onto the sample via an F-theta lens 124. Alternatively, the laser can be forcused on the sample by setting the focus position, i.e. height, of the off-axis microscope, which has short focal length, to be coincident with the focus position of the laser beam, and moving the sample height until it is in-focus at the microscope. At step 244, the laser is scanned across a region to be cross-sectioned with a scan-head 122. At step 246, the process is stopped when a desired cross section is detected via a light detector located under the sample.

FIG. 3 is a flow diagram of an exemplary process for cross sectioning a sample held under liquid according to a further aspect or the invention. Step 310 provides for positioning a sample to be cross-sectioned on a sample stage in a liquid bath 220. At step 312, a pulsed laser beam is focused onto the sample via an F-theta lens 124. At step 314, the laser is scanned across a limited region to be cross-sectioned with a scan-head 122 until the limited region is fully ablated to the bottom of the sample to allow liquid to enter the ablated region from the bottom of the opening in the sample. At step 316, the ablation process is continued to ablate a desired region of the sample.

FIG. 4 is a flow diagram of an exemplary process for cross sectioning a sample held under liquid according to a further aspect or the invention. Step 410 provides for positioning a sample to be cross-sectioned on a sample stage in a liquid bath 220. At step 412, a pulsed laser beam is focused onto the sample via an F-theta lens 124. At step 414, the laser is paused to allow bubbles and ablated material to be cleared from the liquid bath 220. At step 416, the ablation process is continued to ablate a desired region of the sample. Pausing of the ablation process to clear ablated material and bubbles in the liquid may be repeated as necessary.

Although the invention has been described in detail above, it is expressly understood that it will be apparent to persons skilled in the relevant art that the invention may be modified without departing from the spirit of the invention. Various changes of form, design, or arrangement may be made to the invention without departing from the spirit and scope of the invention. Therefore, the above-mentioned description is to be considered exemplary, rather than limiting, and the true scope of the invention is that defined in the following claims.

No element, act, or instruction used in the description of the present application should be construed as critical or essential to the invention unless explicitly described as such. Also, as used herein, the article “a” is intended to include one or more items. Further, the phrase “based on” is intended to mean “based, at least in part, on” unless explicitly stated otherwise.

What is claimed is:

1. An apparatus for milling of a sample with a laser beam comprising:
a pulsed laser,
a scan head configured to scan said pulsed laser in two directions perpendicular to the laser beam to create a scanned laser beam, and
an F-theta lens configured to focus said scanned laser beam onto said sample.

2. The apparatus of claim 1 wherein said laser is turned on in a burst of a limited number of pulses and wherein the burst of a limited number of pulses is repeated at a fixed repetition rate.

3. The apparatus of claim 2, wherein each of repeated bursts is between 2 and 50 pulses long.

4. The apparatus of claim 1 wherein said pulsed laser has a power of between 1 and 50 watts.

5. The apparatus of claim 1 wherein said pulsed laser has a wavelength between 1050 nanometers (nm) and 350 nm.

6. The apparatus of claim 1 wherein said pulsed laser has a pulse length between 250 femtoseconds and 750 picoseconds.

7. The apparatus of claim 1 wherein said F-theta lens is configured to produce a beam spot size between 10 micron and 100 micron at the sample.

8. The apparatus of claim 1 further comprising a camera and a beam splitter, said beam splitter configured to transmit said pulsed laser beam to the sample and to transmit an image of the sample to said camera.

9. The apparatus of claim 1 further comprising a liquid bath for immersion of the sample, said liquid bath comprising a recirculating system comprising a filter to remove bubbles from the liquid.

10. The apparatus of claim 9, wherein said recirculating system is configured to maintain one of:
a constant liquid level over a top surface of the sample, or
a constant liquid level over an ablated surface of the sample.

11. The apparatus of claim 1 further comprising a gas extractor configured to direct a plasma plume from ablation of the sample to a gas analyzer

12. The apparatus of claim 1 further comprising a light detector located beneath the sample and configured to sense said pulsed laser beam after said pulsed laser beam has cut through the sample

13. A method of using a pulsed laser to cut a cross section in a package containing one or more integrated circuits, comprising;
placing the package in a liquid bath on a movable stage,
exposing the package to a scanned pulsed laser beam.

14. The method of claim 13, wherein said pulsed laser beam is energized in a series of bursts of pulses, each burst being between 2 and 50 pulses in duration.

15. The method of claim 13 wherein said pulsed laser beam has a power level between 1 and 50 watts, a pulse time between 250 fs and 750 ps, a wavelength between 1050 nm and 350 nm, and a spot size at the package between 10 micron and 100 micron.

16. The method of claim 13 further comprising pausing said exposing to allow liquid to flow into a region of the package after the region has been ablated by the pulsed laser beam and resuming said exposing after the liquid has filled said region.

17. The method of claim 13 further comprising:
milling a first region completely through the package with said pulsed laser beam to allow liquid to flow into said first region to liquid from below the package and
milling a second region contiguous with said first region after said first region has filled with liquid.

18. The method of claim 13 further comprising:
detecting, by a light detector positioned below the sample, said pulsed laser beam after said pulsed laser beam has cut through the package, and
terminating said exposing when the light detector detects that a desired cross section has been made.

19. The method of claim 13 further comprising:
recirculating liquid from said liquid bath through a filter to remove ablated material and bubbles created by said pulsed laser ablating the package.

20. An apparatus for milling a cross section in a semiconductor package with a laser beam, comprising:
a pulsed laser,
a scan head configured to scan said pulsed laser in two directions perpendicular to the laser beam to create a scanned laser beam,
a lens configured to focus said scanned laser beam onto said sample,
said pulsed laser being energized in a series of bursts, each of said bursts being between 2 and 50 pulses in duration,
wherein said pulsed laser has a power between 1 and 50 watts, a wavelength between 1050 nm and 350 nm and a spot size at the package between 10 and 100 micron.
